(19) United States
(12) Patent Application Publication
(10) Pub. No.: US 2022/0181512 A1
(43) Pub. Date: Jun. 9, 2022

(54) TOOL FOR COLLECTIVE TRANSFER OF MICROCHIPS FROM A SOURCE SUBSTRATE TO A DESTINATION SUBSTRATE

(71) Applicant: Commissariat à l'Énergie Atomique et aux Énergies Alternatives, Paris (FR)

(72) Inventor: Stéphane Caplet, Sassenage (FR)

(73) Assignee: Commissariat à l'Énergie Atomique et aux Énergies Alternatives, Paris (FR)

(21) Appl. No.: 17/534,356

(22) Filed: Nov. 23, 2021

(30) Foreign Application Priority Data
Dec. 3, 2020 (FR) 2012635

(51) Int. Cl. H01L 33/00

(52) U.S. Cl. CPC H01L 33/005

(57) ABSTRACT

A tool for the collective transfer of microchips from a source substrate to a destination substrate, said tool comprising a plate having first and second opposite faces and a plurality of microchip receiving areas on the side of the first face, the plate comprising a through opening opposite each receiving area.

### CROSS-REFERENCE TO RELATED APPLICATION

This application claims priority to French application number 2012635, filed Dec. 3, 2020, the contents of which is incorporated by reference in its entirety.

### TECHNICAL FIELD

The present disclosure relates generally to the field of assembling microchips on a substrate, with a view to producing an emissive light-emitting diode (LED) image display device, for example, such as a television screen, a computer screen, a smartphone, a digital tablet, etc.

### BACKGROUND ART

A method for manufacturing an image display device comprising a plurality of elementary electronic microchips arranged in a matrix on a single transfer substrate has already been proposed in patent application EP3381060. According to this method, the microchips and the transfer substrate are manufactured separately. Each microchip comprises an LED stack and an LED driver circuit. The driver circuit comprises a connection face opposite the LED, comprising electrical connection pads intended to be connected to the transfer substrate, to control the microchip. The transfer substrate comprises a connection face comprising electrical connection pads for each microchip, intended to be connected to the respective electrical connection pads of the microchip. The chips are then mounted on the transfer substrate with their connection faces facing the connection face of the transfer substrate and attached to the transfer substrate so as to connect the electrical connection pads of each microchip to the corresponding electrical connection pads of the transfer substrate.

Due to the relatively small dimensions of microchips, their assembly on the transfer substrate is difficult to achieve.

### SUMMARY OF INVENTION

In one embodiment, a tool is provided for the collective transfer of microchips from a source substrate to a destination substrate, said tool comprising a plate having first and second opposite faces, and, on the side of the first face, a plurality of microchip receiving areas, with the plate comprising a through opening facing each receiving area.

According to one embodiment, each through opening is adapted to channel a suction flow generated on the side of the second face of the plate, so as to keep a microchip packed against each receiving area.

According to one embodiment, the plate comprises a boss in each receiving area, on the side of its first face, at least partially surrounding the opening.

According to one embodiment, in each receiving area, the boss forms a frame completely surrounding the through opening and laterally delimiting a cavity into which the through opening opens.

According to one embodiment, the plate comprises one or more support pillars on the side of its first face, in each receiving area, extending into the cavity delimited laterally by the boss.

According to one embodiment, the plate has a roughness of between 10 and 50 nm on the side of its first face.

According to one embodiment, the plate comprises a common cavity on the side of its second face, into which the through openings open, said cavity being intended to be connected to a suction source.

According to one embodiment, the plate comprises one or more support pillars on the side of its second face, extending into the common cavity.

According to one embodiment, the plate comprises a stack of a substrate of a semiconductor material, a dielectric layer and a semiconductor layer.

According to one embodiment, each via opening comprises a first portion, extending through the substrate and the dielectric layer, and a second portion, extending through the semiconductor layer, the first portion having lateral dimensions greater than the lateral dimensions of the second portion.

Another embodiment provides a device for the collective transfer of microchips from a source substrate to a destination substrate, comprising a transfer tool as defined above, and a support for holding the tool, the support being adapted to collectively connect the through openings to a suction source.

According to one embodiment, the transfer tool is kept attached to the support by suction, by means of a second suction source.

Another embodiment provides a method for transferring microchips from a source substrate to a destination substrate by means of a transfer tool, as defined above, wherein each microchip comprises an LED and an LED driver circuit.

### BRIEF DESCRIPTION OF DRAWINGS

The foregoing features and advantages, as well as others, will be described in detail in the following description of specific embodiments given by way of illustration and not limitation with reference to the accompanying drawings, in which:

FIG. 1A is a view from below, schematically showing an example of a tool for transferring microchips from a source substrate to a destination substrate according to one embodiment;

FIG. 1B is a cross-sectional view of the tool of FIG. 1A;

FIG. 1C is another cross-sectional view of the tool of FIG. 1A;

FIG. 1D is a view from above of the tool of FIG. 1A;

FIG. 2 is a cross-sectional view, schematically showing a transfer device comprising a transfer tool of the type described in connection with FIGS. 1A, 1B, 1C and 1D;

FIG. 3 is a view from below, schematically showing a tool support of the device of FIG. 2;

FIG. 4 is a cross-sectional view, schematically showing another example of a tool for transferring microchips from a source substrate to a destination substrate according to one embodiment;

FIG. 5A is a cross-sectional view, schematically and partially showing a variant embodiment of the transfer tool of FIGS. 1A, 1B, 1C and 1D;

FIG. 5B is a view from below of the tool of FIG. 5A;

FIG. 6A is a cross-sectional view, schematically and partially showing another variant embodiment of the transfer tool of FIGS. 1A, 1B, 1C and 1D; and

FIG. 6B is a view from below of the tool of FIG. 6A.

### DESCRIPTION OF EMBODIMENTS

Like features have been designated by like references in the various figures. In particular, the structural and/or functional features that are common among the various embodiments may have the same references and may dispose identical structural, dimensional and material properties.

For the sake of clarity, only the operations and elements that are useful for an understanding of the embodiments described herein have been illustrated and described in detail. In particular, the various applications that can benefit from the described transfer tools have not been detailed.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following disclosure, unless indicated otherwise, when reference is made to absolute positional qualifiers, such as the terms “front”, “back”, “top”, “bottom”, “left”, “right”, etc., or to relative positional qualifiers, such as the terms “above”, “below”, “higher”, “lower”, etc., or to qualifiers of orientation, such as “horizontal”, “vertical”, etc., reference is made to the orientation shown in the figures.

Unless specified otherwise, the expressions “around”, “approximately”, “substantially” and “in the order of” signify within 10%, and preferably within 5%.

Here, making a transfer tool for collectively (simultaneously) transferring a plurality of separate microchips from a source substrate to a destination substrate is of particular interest.

By way of example, microchips are formed from a single semiconductor plate. The microchips are all identical, for example, within manufacturing dispersions. The source substrate can be a carrier film, such as an adhesive film, on which the microchips rest after a singularization step. By way of example, the microchips may be elementary pixels of a display screen. Each microchip may comprise only one LED, for example, or one LED and a circuit for controlling the LED, or a plurality of LEDs and a circuit for controlling said plurality of LEDs. By way of example, each microchip comprises a stack of an LED and an LED control circuit as described in the aforementioned patent application EP3381060.

According to one aspect of the described embodiments, the transfer tool is adapted to draw a plurality of microchips simultaneously from the source substrate by suction, and then transfer the microchips drawn to a destination substrate or transfer substrate.

The transfer substrate comprises a connection face, for example, comprising one or more electrical connection pads for each microchip, intended to be connected respectively to the corresponding electrical connection pads of the microchip. The microchips can be attached to the transfer substrate with the connection faces facing the connection face of the transfer substrate by means of the transfer tool. The transfer tool can be applied like a pad against the connection face of the transfer substrate, so as to set the microchips on the transfer substrate and electrically connect the connection pads of the microchips to the corresponding connection pads of the transfer substrate. The transfer tool can then be removed, leaving the microchips in place on the transfer substrate.

In a variant, the transfer tool can be used to perform a collective transfer of microchips from a source substrate to a destination substrate without electrically connecting the microchips to the destination substrate. In this case, the microchips may not have electrical connection pads on the side of their face facing the destination substrate. For example, the microchips may be bonded to the destination substrate by means of an adhesive layer.

The pitch of the microchips (i.e. the center-to-center distance between two adjacent microchips) on the transfer substrate may be a multiple, greater than 1, for example, of the pitch of the microchips on the source substrate. For example, the microchip pitch on the transfer tool is equal to the microchip pitch on the transfer substrate.

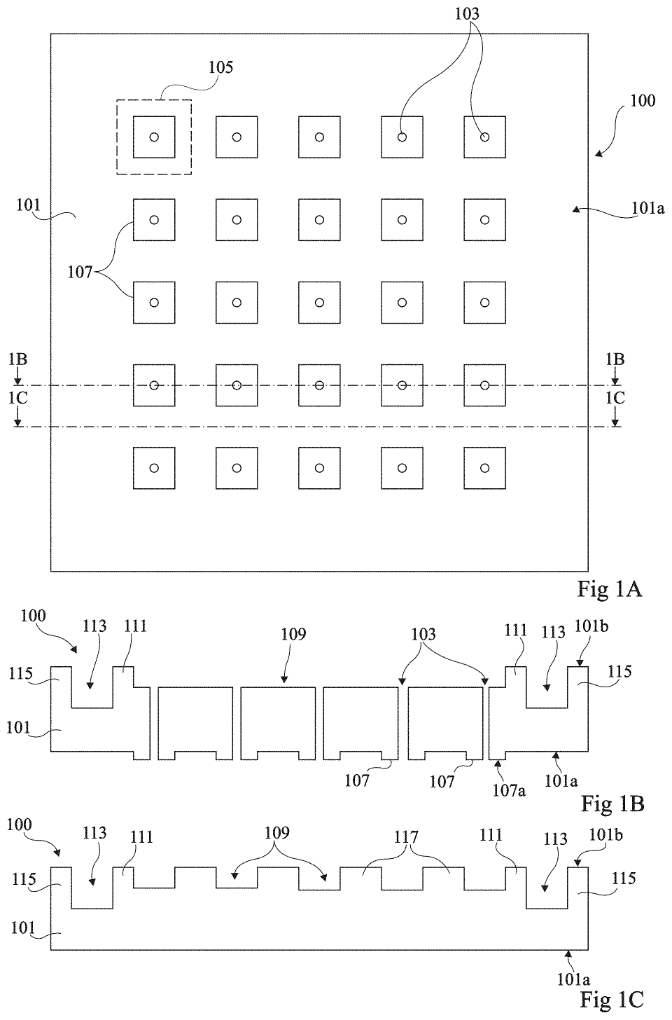

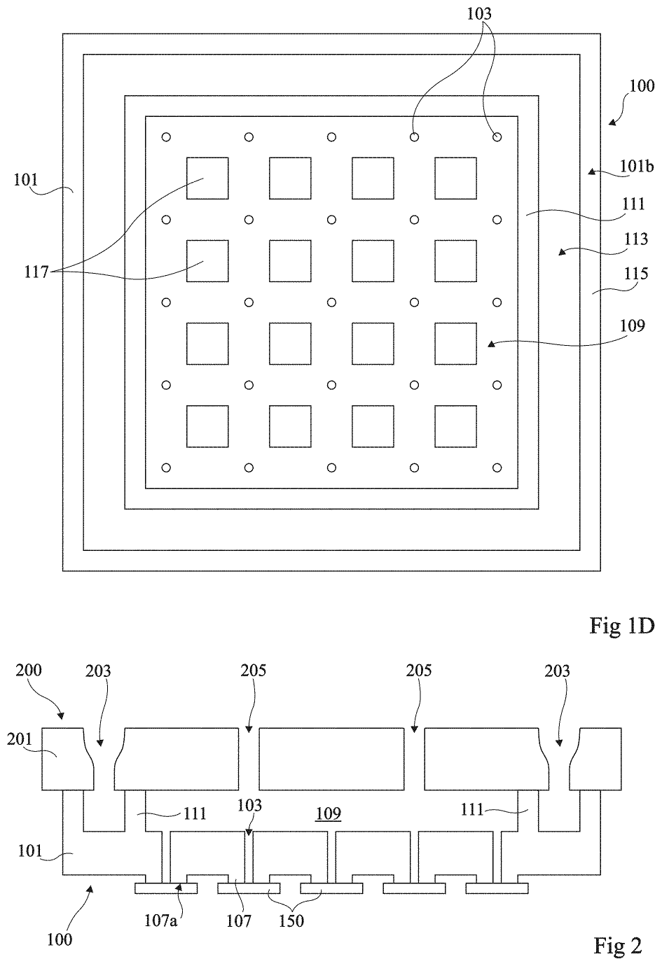

FIGS. 1A, 1B, 1C, and 1D schematically show an example of a tool 100 for transferring microchips from a source substrate to a destination substrate according to one embodiment. FIG. 1A is a view from below of the transfer tool. FIG. 1B is a cross-sectional view along the 1B-1B plane of FIG. 1A. FIG. 1C is a cross-sectional view along plane 1C-1C of FIG. 1A. FIG. 1D is a view from above of the transfer tool.

The transfer tool 100 comprises a plate 101, made of a semiconductor material, for example, such as silicon. The plate 101 comprises first and second opposite main faces, 101a and 101b, corresponding to the lower face and upper face, respectively, in the orientation of the cross-sectional views in FIGS. 1B and 1C. The thickness of the plate 101 is between 300 μm and 1 mm, for example, of the order of 725 μm, for example. The lateral dimensions of the plate 101 are between 1 mm and 10 cm, for example. When viewed from above or below, the plate 101 has a generally square or rectangular shape, for example. However, the described embodiments are not limited to this particular case.

The plate 101 comprises a plurality of through openings 103, extending vertically from the upper side 101b to the lower side 101a of the plate. Each opening 103 has lateral dimensions on the side of the face 101a that are smaller than the dimensions of the microchips to be handled, such as lateral dimensions that are at least twice and preferably at least 5 times smaller than the lateral dimensions of the microchips. For example, the microchips to be handled have lateral dimensions of between 5 and 500 μm, between 5 and 100 μm or between 5 and 50 μm, for example. The lateral dimensions of the openings 103 at the lower side 101a of the plate 101 are between 1 and 100 μm or between 5 and 50 μm, for example.

The openings 103 form suction holes for drawing up microchips from a source substrate and transferring them to a destination substrate. More particularly, during a transfer operation, air is drawn through the openings 103 from the upper side 101b of the plate 101 by means of a suction source (not shown). The plate 101 is then placed opposite the source substrate, with the lower face 101a turned towards the microchips, and brought close to the microchips, until coming into contact with the face of the microchips opposite the source substrate, for example. The microchips located facing the openings 103 of the plate 101 are then packed, by suction, against the lower face 101a of the plate 101. When the transfer tool is moved away from the source substrate, the microchips sucked in this way become detached from the source substrate and remain packed against the lower face of the plate 101. The microchips that are not located facing the suction holes 103 remain on the source substrate. The transfer tool is then moved to the destination substrate, by means of a motorized arm (not shown), for example, and then applied against the destination substrate, with the lower face turned towards the receiving face or connection face of the destination substrate. The microchips are thus brought into contact, by their face opposite the plate 101, with the receiving face of the destination substrate. The suction source can then be interrupted to release the microchips, which thus remain on the destination substrate when the transfer tool is removed.

One advantage of this transfer mode is that it allows a plurality of microchips to be transferred collectively onto a destination substrate, which can be advantageous in making display screens in particular of the type described in the aforementioned patent application EP3381060. In addition, the transfer tool allows pressure to be exerted on the microchips as they are applied to the destination substrate. This can be advantageous for attaching and electrically connecting the microchips to the destination substrate. This is particularly advantageous in the case where the microchips are provided with micro-inserts such as microtubes on the side of their face for connection to the destination substrate, made of an electrically conductive material such as tungsten, formed by a method of the type described in patent application US2011/094789, for example, intended to be inserted by pressure into electrical connection areas of the destination substrate. In a variant, the micro-inserts may be formed on the connection face of the destination substrate and be inserted by pressure into electrical connection pads of the microchips.

On the side of its lower face, the plate 101 comprises a plurality of receiving areas 105, each intended to receive a microchip at a 1 to 1 ratio (one single microchip per receiving area and one single receiving area per microchip). In this example, the plate 101 comprises a single through opening 103 opposite each docking area 105. The lateral dimensions of the docking areas are substantially equal to the lateral dimensions of the microchips to be handled. The pitch of the receiving areas (i.e. the center-to-center distance between two adjacent receiving areas) defines the microchip pitch on the transfer tool. This pitch is equal or substantially equal to the microchip pitch on the destination substrate, for example. The microchip pitch on the transfer tool is between 100 and 500 μm, for example, around 200 μm, for example. The microchip receiving areas 105 are arranged in rows and columns in a matrix, for example. In the example shown, the transfer tool comprises a matrix of 5×5 receiving areas 105, i.e. a transfer capacity of 25 microchips simultaneously. Of course, the described embodiments are not limited to this particular case.

In the example of FIGS. 1A to 1D, in each receiving area 105, the plate 101 has a boss 107 on the side of its lower face 101a, projecting from the face 101a, at least partially surrounding the opening 103. In the example shown, each boss 107 has a square shape (when viewed from below), with the center of the opening 103 substantially coinciding with the center of the square. However, the bosses 107 may have any other shape. In addition, each receiving area 105 may have a plurality of separate bosses 107. The lateral dimensions of the bosses 107 are less than or equal to the lateral dimensions of the microchips to be handled, for example. In a variant, the lateral dimensions of the bosses 107 are slightly larger than the lateral dimensions of the microchips. For example, the lateral dimensions of the bosses 107 are 0.5 to 5 μm larger than the lateral dimensions of the microchips.

One advantage of providing the bosses 107 is that, when the transfer tool 100 is put in contact with the source substrate microchips, only the microchips opposite an opening 103 come into contact with the lower surface 101a of the plate 101 at the lower surface 107a of the bosses 107. This avoids any risk of accidental removal of other microchips from the source substrate (e.g. by electrostatic interaction, van der Waals forces, etc.). The height (thickness) of the bosses 107 is between 100 nm and 20 μm, for example.

In a variant, the bosses 107 may be omitted, with the lower surface of the plate 101 then being substantially flat.

Also in order to limit the risks of undesired microchip adhesion, the lower face of the plate 101 may have a controlled roughness, a roughness of the order of 10 to 50 nm, for example. Outside the receiving areas 105, this roughness makes it possible to limit the risks of accidental removal of microchips from the source substrate. Inside the receiving areas (and in particular, in the presence of the bosses 107, on the contact face 107a of the bosses), this roughness makes it easier to release the microchips (in particular, by limiting the risk of having residual van der Waals forces that would hold the microchip that is to be released) and to deposit them on the destination substrate when the suction is interrupted. The roughness of the underside of the plate 101 may, be achieved by photolithography and etching, for example, by chemical treatment, or by depositing an additional layer (not shown) of controlled roughness.

In the example of FIGS. 1A to 1D, the plate 101 has a cavity 109 on the side of its upper face 101b, into which the through openings 103 open. The cavity 109 allows the suction flow to be distributed to the various openings 103. The cavity 103 is laterally delimited by a peripheral wall 111, ensuring the sealing of the suction. In a variant, the cavity 109 can be replaced by a network of channels to distribute the suction flow, connecting the through openings 103 on the side of the upper face 101b of the plate 101 to each other. The depth of the cavity 109 is between 10 and 300 μm, for example.

The transfer tool 100 is intended to be mounted on a loader or support 200 for holding and handling the tool, inter alia, and for connecting the cavity 109 to a suction source.

FIG. 2 is a cross-sectional view schematically showing the transfer tool 100 mounted on the support 200, further showing microchips 150 held flat against the bosses 107 of the receiving areas 105 by suction, via the openings 103 and the cavity 109.

In this example, the support 200 comprises a plate 201 closing the cavity 109 by its upper side. More particularly, in the example shown, the plate 201 is supported against the upper side of the peripheral wall 111 of the transfer tool 100, by its lower side.

The transfer tool 100 can be fixed to the support 200 by any suitable fixing means, such as by magnetization, by suction, by means of clamps or clips, etc.

In the example shown, the transfer tool 100 is adapted to be affixed to the support 200 by suction. For this purpose, the transfer tool 100 comprises, a non-through peripheral channel 113 on the side of the upper face 101b of the plate 101, laterally delimited by the peripheral wall 111 on the one hand, and by a second peripheral wall 115 of the same height as the wall 111 on the other hand.

In this example, the plate 201 of the support 200 closes the peripheral channel 113 by its upper face. More particularly, in the example shown, the plate 201 is supported against the upper face of the peripheral walls 111 and 115 of the transfer tool 100, by its lower face.

The plate 201 of the support 200 comprises one or more through openings 203 (several in the example shown) facing the peripheral channel 113 of the tool 100. Each opening 203 is intended to be connected to a first suction source (not shown), making it possible to create the vacuum in the peripheral channel 113 so as to keep the transfer tool 100 packed against the lower face of the support 200. A conduit, not shown, may be provided to connect each opening 203 to the first suction source.

The plate 201 of the support 200 further comprises one or more through openings 205 (several in the example shown) facing the cavity 109 of the tool 100. Each opening 205 is intended to be connected to a second suction source (not shown), making it possible to create the vacuum in the cavity 109 so as to keep the microchips 150 packed against the lower face of the transfer tool, facing the openings 103. A conduit, not shown, may be provided to connect each opening 205 to the second suction source.

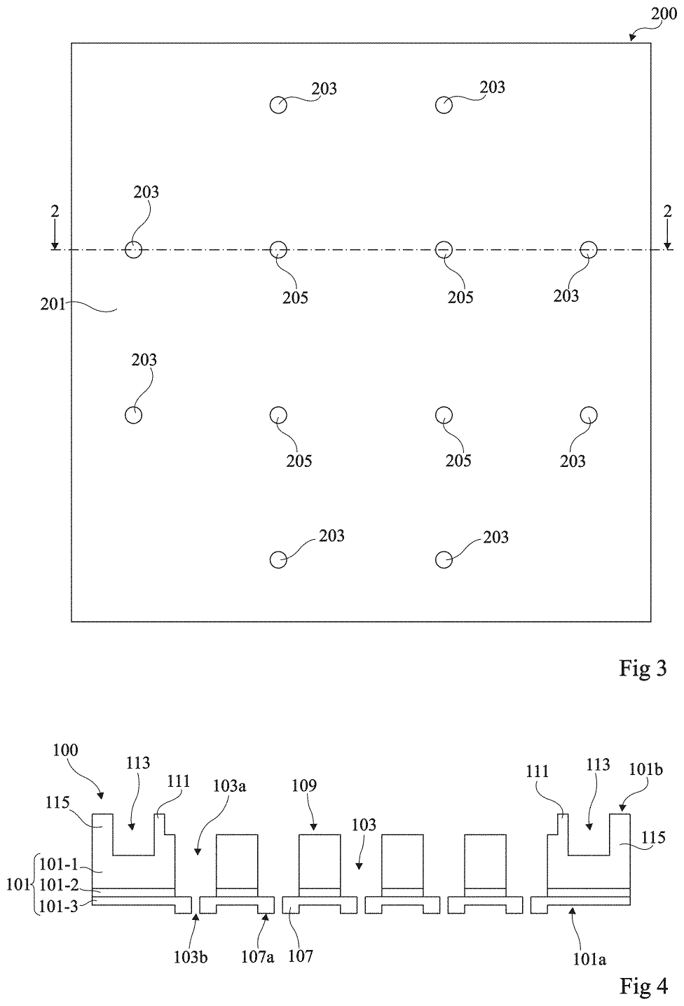

FIG. 3 is a view from below of the support 200 of FIG. 2. The cross-sectional plane of FIG. 2 corresponds to plane 2-2 in FIG. 3, for example.

In the example shown in FIGS. 1A through 1D, the transfer tool comprises one or more pillars or studs 117 (several in the example shown) for supporting the plate 101, on the side of the upper surface 101b of the plate 101. The pillars 117 extend vertically from below of the cavity 109 to the upper side of the cavity 109. In other words, in this example, the upper face of the pillars 117 is substantially flush (coplanar) with the upper face of the peripheral wall 111 laterally bounding the cavity 109. Thus, when the transfer tool 100 is mounted on the support 200, the upper face of the pillars 117 comes into contact with the lower face of the plate 201. This makes it possible to support the transfer tool plate 101 and prevents it from flexing under the effect of the suction. The pillars 117 are preferably evenly distributed over the upper surface of the plate 101. In the example shown, the pillars 117 viewed from above are square in shape, and are arranged in a matrix in rows and columns. More generally, the pillars 117 may have any other shape and/or arrangement to support the plate 101 during suction. In a variant, the support pillars 117 may be omitted. Where the cavity 109 is replaced by a network of channels for distributing the suction flow, the support pillars 117 may correspond to the side walls laterally separating the channels.

FIG. 4 is a cross-sectional view showing a variant embodiment of the transfer tool 100 of FIGS. 1A through 1D in more detail.

In this variant, the plate 101 is a semiconductor on insulator (SOI) structure, comprising a stack of a solid semiconductor substrate 101-1, of single crystal silicon, for example, a dielectric 101-2, of silicon oxide. for example, and a semiconductor layer 101-3, of monocrystalline silicon, for example. In this example, the dielectric layer 101-2 is in contact with the underside of the substrate 101-1 with its upper side, and the semiconductor layer 101-3 is in contact with the underside of the dielectric layer 101-2 with its upper side.

The substrate 101-1 has a thickness of between 250 μm and 1 mm, for example, of the order of 725 μm, for example. The dielectric layer 101-2 has a thickness of between 0.4 and 4 μm, for example. The semiconductor layer 101-3 has a thickness of between 20 and 200 μm, for example.

In this example, the upper side 101b of the plate 101 corresponds to the upper side of the substrate 101-1, and the lower side of the plate 101 corresponds to the lower side of the semiconductor layer 101-3.

The peripheral channel 113 for attaching the tool to the substrate 200, as well as the cavity 109, are formed in an upper portion of the thickness of the substrate 101-1, by photolithography and etching, for example, or by any other micromachining method, such as laser etching.

In this example, each through opening 103 comprises an upper portion 103a having relatively large lateral dimensions, between 30 and 100 μm, for example. In this example, the portion 103a extends vertically into the substrate 101-1 from the bottom of the cavity 109, to the upper surface of the semiconductor layer 101-3. The portion 103a is formed by photolithography and etching, for example, stopping on the upper side of the dielectric layer 101-2, and then removing the exposed portion of the dielectric layer 101-2. Each opening 103 further comprises a lower portion 103b, having lateral dimensions smaller than the lateral dimensions of the upper portion 103a, between 1 and 10 μm, for example. In a variant (not shown), the lower portion 103b of the opening 103 may include a plurality of separate through holes. The lower portion 103b extends vertically from the upper side of the semiconductor layer 101-3 at the bottom of the upper portion 103a to the lower side 101a of the semiconductor layer 101-3. The portion 103b is formed by photolithography and etching, for example, with a different etch mask from that used to form the portion 103a. One advantage is that this makes it possible to form openings 103 having very small lateral dimensions on the side of the face lower 101a of the plate 101, despite a relatively large overall thickness of the plate 101. Although the holes 103a and 103b are coaxial in the example shown, the embodiments described are not limited to this particular case. Thus, the holes 103a and 103b may be unaligned, as long as they remain communicating.

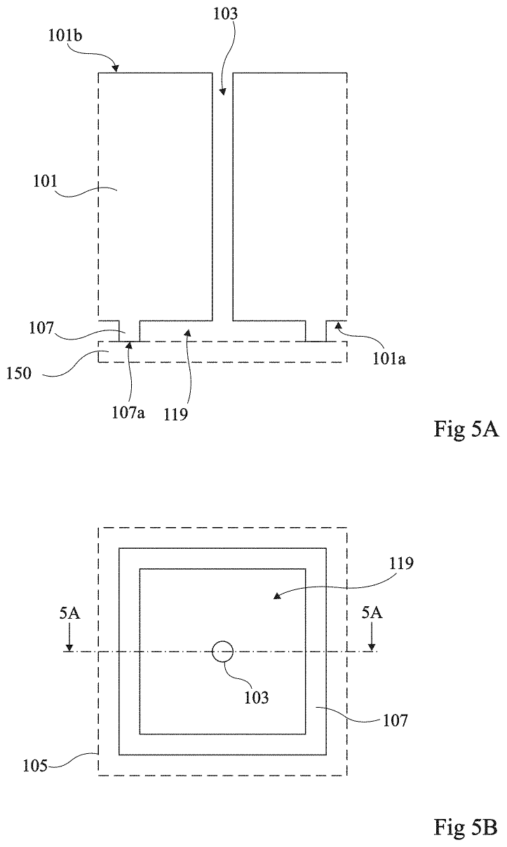

FIGS. 5A and 5B illustrate a variant embodiment of the transfer tool 100 described in connection with FIGS. 1A through 1D. FIG. 5B is a magnified partial view of the tool at a microchip receiving area 105, from below. FIG. 5A is a cross-sectional view along the 5A plane of FIG. 5B. In FIG. 5A, a microchip 150 has been shown schematically by dashed lines.

In this variant, the boss 107 present on the upper side at the receiving area 105 has the shape of a frame surrounding the opening 103, in a view from below. The frame 107 has inner lateral dimensions greater than the lateral dimensions of the opening 103. Thus, the frame 107 laterally delimits a cavity 119 with lateral dimensions greater than the lateral dimensions of the opening 103, into which the opening 103 opens.

The lateral dimensions of the frame 107 are less than or equal to the lateral dimensions of the microchips 150 to be handled, for example. When a microchip is brought into contact with the lower face of the frame 107, the lower face of the frame 107 closes the cavity 119. The cavity 119 is then depressurized due to the suction applied through the opening 103. In a variant, the outer lateral dimensions of the frame 107 may be slightly larger than the lateral dimensions of the microchips, such as 0.5 to 5 μm larger than the lateral dimensions of the microchips.

One advantage of the variant embodiment of FIGS. 5A and 5B is that the frame 107 increases the surface area of the microchip 150 subject to suction, and thus improves the grip of the microchips.

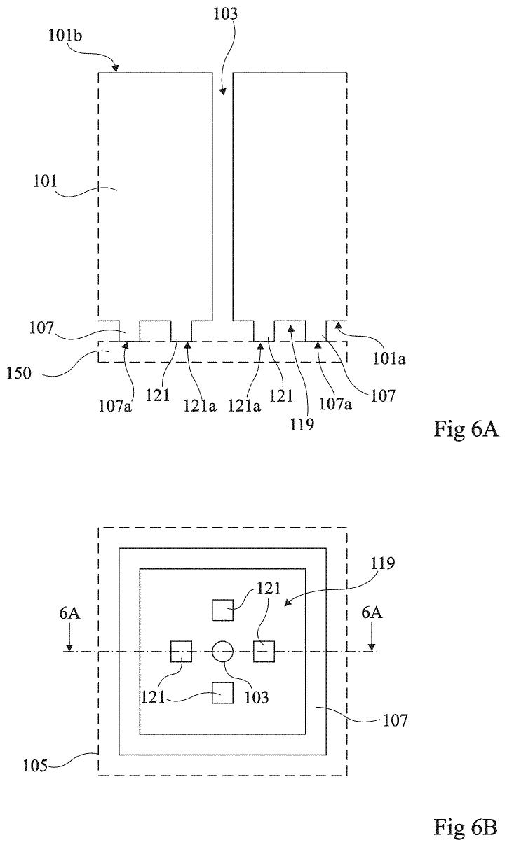

FIGS. 6A and 6B illustrate another variant embodiment of the transfer tool 100 described in connection with FIGS. 1A through 1D. FIG. 6B is a magnified partial view of the tool at a microchip receiving area 105, from below. FIG. 6A is a cross-sectional view along the 6A plane of FIG. 6B. In FIG. 6A, a microchip 150 is shown schematically by dashed lines.

In this variant, the boss 107 present on the upper side at the receiving area 105, as in the example of FIGS. 5A and 5B, has the shape of a frame surrounding the opening 103, in a view from below.

In the variant shown in FIGS. 6A and 6B, the transfer tool further comprises one or more (in the example shown, more than one) supporting pillars 121 on the underside of the plate 101 at each receiving area 105, within the frame 107. The pillars 121 extend vertically from the upper side of the cavity 119 to the lower side of the cavity 119. In other words, in this example, the underside of the pillars 121 is substantially flush (coplanar) with the underside of the peripheral frame 107. Thus, when the transfer tool 100 comes into contact with a microchip 150, the underside of the pillars 121 comes into contact with the upper side of the microchip. This supports the microchip 150 and prevents it from flexing under the effect of the suction. For example, the pillars 121 are evenly distributed throughout the cavity 119. In the example shown, the pillars 121 are square in shape when viewed from below. More generally, the pillars 121 may have any other shape and/or arrangement to support the microchip 150 during transfer.

In a variant, not shown, in the examples of FIGS. 5A and 5B on the one hand, and 6A and 6B on the other hand, the depth of the cavity 119, i.e. the height of the inner side edge of the frame 107, may be different from, e.g. less than, the height of the projection of the boss 107, i.e. the height of the outer side edge of the frame 107. As an example, the depth of the cavity 119 may be between 0.1 and 2 μm, and the projection height of the boss 107 may be between 0.1 and 20 μm.

In a variant embodiment not shown, the cavity 119 may be formed in a thin layer previously deposited on the underside of the plate 101, such as a silicon oxide or metal layer, with a thickness of between 0.1 and 2 μm for example. The cavity 119 can then extend through the entire thickness of said thin layer, which facilitates its implementation.

Various embodiments and variants have been described. Those skilled in the art will understand that certain features of these embodiments can be combined and other variants will readily occur to those skilled in the art. In particular, the described embodiments are not limited to the example materials and dimensions mentioned in the present description.

Furthermore, the described embodiments are not limited to the embodiment of a display screen in which the microchips 150 each correspond to a pixel on the screen, but apply more generally to the embodiment of any device requiring the transfer of a large number of microchips onto a single substrate.

1. A tool for the collective transfer of microchips from a source substrate to a destination substrate, said tool comprising a plate having first and second opposite faces and a plurality of microchip receiving areas on the side of the first face, the plate comprising a through opening facing each receiving area wherein the plate comprises a boss on the side of its first face, in each receiving area, at least partially surrounding the opening.

2. The tool according to claim 1, wherein each through opening is adapted to channel a suction flow generated on the side of the second face of the plate, so as to keep a microchip packed against each receiving area.

3. The tool according to claim 1, wherein the boss forms a frame in each receiving area, completely surrounding the through opening and laterally delimiting a cavity into which the through opening opens.

4. The tool according to claim 3, wherein the plate comprises one or more support pillars on the side of its first face, in each receiving area, extending into the cavity laterally delimited by the boss.

5. The tool according to claim 1, wherein the plate has a roughness of between 10 and 50 nm, on the side of its first face.

6. The tool according to claim 1, wherein the plate comprises a common cavity on the side of its second face, into which the through openings open, said cavity being intended to be connected to a suction source.

7. The tool according to claim 6, wherein the plate comprises one or more support pillars on the side of its second face, extending into said common cavity.

8. The tool according to claim 1, wherein the plate comprises a stack of a substrate of a semiconductor material, a dielectric layer and a semiconductor layer.

9. The tool according to claim 8, wherein each through opening comprises a first portion, extending through the substrate and the dielectric layer, and a second portion, extending through the semiconductor layer, the first portion having lateral dimensions greater than the lateral dimensions of the second portion.

10. A device for the collective transfer of microchips from a source substrate to a destination substrate, comprising a transfer tool according to claim 1, and a support for holding the tool, the support being adapted to collectively connect the through openings to a suction source.

11. The device according to claim 10, wherein the transfer tool is kept attached to the support by suction, by means of a second suction source.

12. A method for transferring microchips from a source substrate to a destination substrate by means of a transfer tool according to claim 1, wherein each microchip comprises an LED and an LED driver circuit.
